(19) United States
(12) Patent Application Publication
(10) Pub. No.: US 2026/0092366 A1
(43) Pub. Date: Apr. 2, 2026

(54) DIELECTRIC FILM ACTIVATOR, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Jae Sun JUNG, Gyeonggi-do (KR); Seung Hyun LEE, Gyeonggi-do (KR); Jong Moon KIM, Gyeonggi-do (KR)

(21) Appl. No.: 19/113,356

(22) PCT Filed: Oct. 6, 2023
(86) PCT No.: PCT/KR2023/015457

§ 371 Date: Mar. 19, 2025

(30) Foreign Application Priority Data
Oct. 7, 2022 (KR) 10-2022-0128694
Jan. 10, 2023 (KR) 10-2023-0003402
Jan. 13, 2023 (KR) 10-2023-0005228
Oct. 6, 2023 (KR) 10-2023-0133350

(51) Int. Cl. C23C 16/455

(52) U.S. Cl. CPC C23C 16/45534

(57) ABSTRACT

The present invention relates to a dielectric film activator, and a semiconductor substrate and semiconductor device fabricated using the same. According to the present invention, by using a dielectric film activator capable of increasing thin film density while reducing the content of by-product carbon compound between a precursor and reaction gas injected into a dielectric film, the capacitance of a dielectric film may be improved, and thin film density may be increased by a simple process.

### TECHNICAL FIELD

The present invention relates to a dielectric film activator, and a semiconductor substrate and semiconductor device fabricated using the same. More particularly, the present invention relates to a dielectric film activator capable of providing the effect of increasing thin film density while improving capacitance by reducing residual carbon compound impurities between a precursor and reaction gas injected into a dielectric film, and a semiconductor substrate and semiconductor device fabricated using the same.

### BACKGROUND ART

A dielectric substance is an insulator that does not conduct electricity like an insulator, but is polarized in an electric field. In semiconductor devices, dielectric substances play a very important role.

For example, in a capacitor, a material in which electricity is actually stored is a dielectric substance.

In addition, when by-product carbon compounds between a precursor and a reaction gas are mixed with a high dielectric substance (high-k) with a high permittivity, a very large capacitance difference may occur.

The content of residual carbon compound impurities, including impurities between a precursor and reaction gas injected into the dielectric film, is a factor affecting the dielectric and chemical properties. The impurities reduce permittivity, or contaminate a dielectric film or disrupt the crystal arrangement of the dielectric film by absorbing byproducts such as HCl and hydrocarbons derived from the leaving group of a halogen ligand. In this case, the problem of reducing a dielectric constant by reducing the thin film density arises.

Therefore, there is a need to develop a dielectric film activator capable of providing the effect of increasing a dielectric constant by increasing thin film density while reducing the content of residual carbon compound impurities including impurities between a precursor and reaction gas injected into a dielectric substance; a method of forming a dielectric film using the dielectric film activator; and a semiconductor substrate and semiconductor device fabricated using the method.

### RELATED ART DOCUMENTS

### Patent Documents

US Patent Application Publication No. 2020/0316645 (publication date: Oct. 8, 2020)

### DISCLOSURE

### Technical Problem

Therefore, the present invention has been made in view of the above problems, and it is one object of the present invention to provide a high-quality dielectric film capable of increasing thin film density while increasing capacitance by activating a precursor adsorbed on a substrate using a dielectric film activator of a predetermined structure and preventing the by-product carbon compound between the precursor and reaction gas from mixing with a dielectric film;

and a semiconductor substrate and semiconductor device including the high-quality dielectric film.

The above and other objects can be accomplished by the present invention described below.

### Technical Solution

In accordance with one aspect of the present invention, provided is a dielectric film activator providing an activated substrate-adsorbed precursor by exchanging a first ligand directly connected to a central metal of a precursor adsorbed on a substrate with a second ligand included in the dielectric film activator.

For example, the central metal of the precursor may be a group 4 atom.

As a specific example, the central metal of the precursor may be Hf or Zr.

The precursor molecule adsorbed on the substrate may include one or more selected from a structure represented by Chemical Formula 1 below and a structure represented by Chemical Formula 2 below.

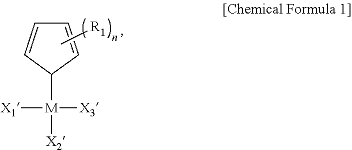

wherein M is Zr or Hf; R₁ is independently hydrogen or an alkyl group having 1 to 4 carbon atoms; n is an integer from 0 to 5; X′₁, X′₂, and X′₃ are independently selected from —NR′₁R′₂ or —OR′₃, Cl, or F; and R′₁ to R′₃ are independently hydrogen or an alkyl group having 1 to 6 carbon atoms.

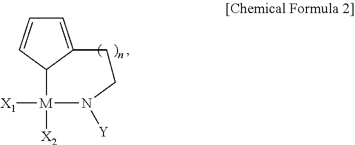

wherein M is Zr or Hf; X₁ and X₂ are independently —NR₁R₂ or —OR₃, Cl, or F; R₁ to R₃ are independently hydrogen or an alkyl group having 1 to 6 carbon atoms; Y is an alkyl having 1 to 6 carbon atoms; and n is 1 or 2.

The precursor molecule adsorbed on the substrate may have a structure in which four ligands independently selected from —NR′₁R′₂ or —OR′₃, Cl, or F are bonded to the central metal. Here, the central metal may be Zr or Hf, and R′₁ to R′₃ may be independently hydrogen or an alkyl group having 1 to 6 carbon atoms.

The first and second ligands may independently include a halogen, a halogen and oxygen or carbon and hydrogen simultaneously, or nitrogen and carbon simultaneously.

The first ligand may be the ligand of Chemical Formula 1 or 2, the ligand of the precursor adsorbed on the substrate may include one or more selected from chlorine, fluorine, and bromine in addition to the first ligand, and the dielectric film activator may include one or more halogens selected from iodine and bromine.

The dielectric film activator may be hydrogen iodide (HI), hydrogen bromide (HBr), or a mixed gas obtained by mixing hydrogen iodide (HI) or hydrogen bromide (HBr) and an inert gas in a molar fraction of 1 to 99.

Reaction with a reaction gas injected before or after injection of the precursor may be promoted by the activated substrate-adsorbed precursor, and at the same time, a content of residual carbon compound impurities may be reduced.

Reduction in the content of residual carbon compound impurities may include reduction in a content of by-product carbon-oxygen impurities generated by bonding between a precursor desorption ligand and a reaction gas and reduction in a content of carbon compound impurities not desorbed the precursor.

Reduction in the content of non-desorbed carbon compound impurities may be due to exchange of the ligand of the precursor adsorbed on the substrate with a dielectric film activator included in the dielectric film activator.

The reaction gas may include one or more selected from H₂O, H₂O₂, N₂O, NO₂, O₂, O₃, and O radical.

A precursor adsorption state before the ligand exchange may be represented by Chemical Formula 3-1 below, and a precursor adsorption state after the ligand exchange may be represented by Chemical Formula 3-2 below.

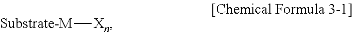

wherein M is Hf or Zr; n is an integer from 1 to 4; and X is ligand species of Chemical Formulas 1 and 2, F, or Cl and is the same or different.

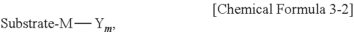

wherein M is Hf or Zr; m is an integer from 1 to 4; and Y is Br or I.)

The substrate may be a silicon wafer, insulating film, or dielectric film having an —H or —OH terminal group.

The dielectric film may be a deposition film.

Here, the deposition may include atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

In accordance with another aspect of the present invention, provided is a semiconductor substrate including a substrate; and a dielectric film,
wherein the dielectric film is a film deposited using the dielectric film activator described above.

The dielectric film may have a multi-layer structure with two or more layers.

The dielectric film may have a deposition rate (based on a thin film deposited at 300° C.) of 0.5 Å/cycle or more as measured on SiO₂ or Si.

The dielectric film may have a thin film density of 9.8 g/cm³ or more as measured on SiO₂ or Si.

The dielectric film may have a C impurity content of 1000 counts/s or less as measured by SIMS (based on a thin film deposited at 300° C.) on SiO₂ or Si.

In accordance with yet another aspect of the present invention, provided is a semiconductor device including the semiconductor substrate described above.

### Advantageous Effects

According to the present invention, the present invention has an effect of providing a dielectric film activator capable of promoting the reaction with a post-injected reaction gas by an activated substrate-adsorbed precursor while reducing the content of residual carbon compound impurities.

Specifically, when forming a dielectric film, corrosion or deterioration can be prevented and the dielectric properties of a dielectric film can be improved by effectively reducing process by-products while improving density.

In addition, the thickness uniformity of a dielectric film can be improved. In addition, the present invention has an effect of providing a method of manufacturing a dielectric film using the dielectric film activator, and a semiconductor substrate and semiconductor device fabricated using the method.

### DESCRIPTION OF DRAWINGS

FIG. 1 is a diagram for comparing the growth rates depending on deposition temperatures in the dielectric film of Example 1 using a dielectric film activator according to the present invention and the growth rates depending on deposition temperatures in the dielectric film of Comparative Example 1 without using the dielectric film activator.

FIG. 2 is a graph showing the C impurity content analyzed by SIMS in the dielectric film of Additional Example 1 using a dielectric film activator according to the present invention.

FIG. 3 is a graph showing the C impurity content analyzed by SIMS in the dielectric film of Additional Comparative Example 1 without using the dielectric film activator.

### BEST MODE

Hereinafter, a dielectric film activator of the present invention, and a semiconductor substrate and semiconductor device fabricated using the same are described in detail.

The present inventors confirmed that, by using a dielectric film activator capable of increasing thin film density while reducing the content of by-product carbon-oxygen impurities generated by bonding between a precursor desorption ligand and reactant injected into a dielectric film and the content of carbon compound impurities not desorbed from the precursor, when forming a dielectric film, density was improved, corrosion or deterioration was prevented, the dielectric properties and thickness uniformity of the dielectric film were improved, and thus the high-quality dielectric film was provided. Based on these results, the present inventors conducted further studies on the dielectric film to complete the present invention.

Hereinafter, the dielectric film activator, and the semiconductor substrate and semiconductor device including a dielectric film manufactured using the dielectric film activator are described in detail.

In the present disclosure, the dielectric film activator may be a substance that promotes the reaction with a post-injected reaction gas by an activated substrate-adsorbed precursor obtained by activating a precursor adsorbed on a substrate while reducing the mixing of residual carbon compound impurities in a dielectric film.

The central metal of the precursor adsorbed on the substrate described above is a group 4 atom, and the ligand may contain two or more halogens that are the same or different from each other, and may be adsorbed on the substrate.

The central metal may preferably be Hf or Zr.

In the present invention, the precursor compound used to form a dielectric film may be composed of group 4 metals such as Hf and Zr, and may be a linear precursor molecule or a cyclic precursor molecule in which ligands bonded to the central metal are connected, as derivatives with Hf(NMe₂)₄, Zr(NMe₂)₄ and CpZr(NMe₂)₃), CpHf(NMe₂)₃) and Hf, Zr as central metals.

For example, the precursor molecule adsorbed on the substrate may be represented by Chemical Formulas 1 and 2 below.

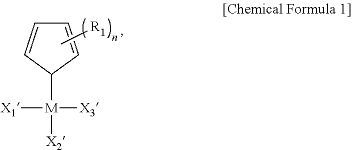

In Chemical Formula 1, M is Zr or Hf; R₁ is independently hydrogen or an alkyl group having 1 to 4 carbon atoms; n is an integer from 0 to 5; X′₁, X′₂, and X′₃ are independently selected from —NR′₁R′₂ or —OR′₃, Cl, or F; and R′₁ to R′₃ are independently hydrogen or an alkyl group having 1 to 6 carbon atoms.

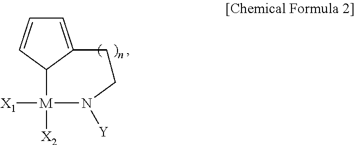

In Chemical Formula 2, M is Zr or Hf; X₁ and X₂ are independently —NR₁R₂ or —OR₃, Cl, or F; R₁ to R₃ are independently hydrogen or an alkyl group having 1 to 6 carbon atoms; Y is an alkyl having 1 to 6 carbon atoms; and n is 1 or 2.

In the case of a precursor having a vapor pressure of 1 mTorr to 100 Torr at 25° C. as a molecule having a transition metal as a central metal atom (M) and one or more ligands of C, N, O, H, and X (halogen), the effect of substituting a ligand with the dielectric film activator described below may be maximized.

In addition, examples of zirconium precursor compounds may include tris(dimethylamido)cyclopentadienyl zirconium of CpZr(NMe₂)₃), (methyl-3-cyclopentadienylpropylamino)bis(dimethylamino) zirconium of Cp(CH₂)₃NM₃Zr(NMe₂)₂, and tetrakis(ethylmethylamido)zirconium of (Me)(Et)N]₄Zr. In this case, the precursor compound may be appropriately filled by the dielectric film activator described later.

Examples of hafnium precursor compounds may include tris(dimethylamido)cyclopentadienyl hafnium of CpHf(NMe₂)₃), (methyl-3-cyclopentadienylpropylamino)bis(dimethylamino) hafnium of Cp(CH₂)₃NM₃Hf(NMe₂)₂, and (tetrakis(ethylmethylamido)hafnium of (Me)(Et)N]₄Hf. In this case, the precursor compound may be appropriately filled by the dielectric film activator described later.

In the present invention, for example, the precursor compound may be mixed with a non-polar solvent and introduced into the chamber. In this case, the viscosity or vapor pressure of the precursor compound may be easily controlled.

The non-polar solvent may preferably include one or more selected from the group consisting of alkanes and cycloalkanes. In this case, an organic solvent with low reactivity and solubility and easy moisture management may be included. In addition, thin film density (step coverage) may be improved even when deposition temperature increases during dielectric film formation.

As a more preferred example, the non-polar solvent may include a C1 to C10 alkane or a C3 to C10 cycloalkane, preferably a C3 to C10 cycloalkane. In this case, reactivity and solubility may be reduced, and moisture management may be easy.

In the present disclosure, C1, C3, and the like indicate the number of carbon atoms.

The cycloalkane may preferably include C3 to C10 monocycloalkanes, and among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase the resistance and impurities within a dielectric film. When the content of the organic solvent is less than the range, the effect of improving thin film density due to solvent addition and the effect of reducing impurities such as chloride (Cl) ions may be reduced.

The first and second ligands may independently include a halogen, a halogen and oxygen or carbon and hydrogen simultaneously, or may independently include nitrogen and carbon simultaneously.

The first ligand may be the ligand of Chemical Formula 1 or 2, the ligand of the precursor adsorbed on the substrate may include one or more selected from chlorine, fluorine, and bromine in addition to the first ligand, and the dielectric film activator may include one or more halogens selected from iodine and bromine.

The dielectric film activator may be hydrogen iodide (HI), hydrogen bromide (HBr), or a mixed gas obtained by mixing hydrogen iodide (HI) or hydrogen bromide (HBr) and an inert gas in a molar fraction of 1 to 99.

A material having a structure in which the aforementioned ligand is bonded to the central metal may be used as a precursor adsorbed on a substrate. Here, a precursor adsorbed on a substrate activated by the dielectric film activator described above may be obtained.

The reaction with a post-injected reaction gas may be promoted by the activated substrate-adsorbed precursor, and at the same time, the content of residual carbon compound impurities may be reduced.

Here, reduction in the content of residual carbon compound impurities may include reduction in a content of by-product carbon-oxygen impurities generated by bonding between a precursor desorption ligand and a reactant and reduction in the content of carbon compound impurities not desorbed the precursor.

Specifically, reduction in the content of non-desorbed carbon compound impurities may be due to exchange of the ligand of the precursor adsorbed on the substrate with a dielectric film activator included in the dielectric film activator.

A precursor adsorption state before the ligand exchange may be represented by Chemical Formula 3-1 below, and a precursor adsorption state after the ligand exchange may be represented by Chemical Formula 3-2 below.

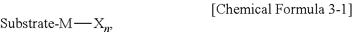

In Chemical Formula 3-1, M is Hf or Zr; n is an integer from 1 to 4; and X is ligand species of Chemical Formulas 1 and 2, F, or Cl and is the same or different.

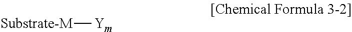

In Chemical Formula 3-2, M is Hf or Zr; m is an integer from 1 to 4; and Y is Br or I.

For example, when the precursor adsorbed on the substrate is CpHf(NMe₂)₃, in the structure of the precursor adsorbed on the substrate activated by the dielectric film activator, in Chemical Formula 3-1 (Substrate-M-Xₙ), M may be Hf, and X, which may be different, may be one Cp ligand and two NMe₂ ligands.

The substrate may be a silicon wafer, insulating film, or dielectric film having an —H or —OH terminal group.

For example, the ligand of the precursor adsorbed on the substrate may be a ligand species represented by Chemical Formula 1 or 2, F, or C.

As another example, the ligand of the precursor adsorbed on the substrate may be independently selected from —NR′₁R′₂ or —OR′₃, Cl, or F. Here, R′₁ to R′₃ are independently hydrogen or an alkyl group having 1 to 6 carbon atoms.

When the precursor adsorbed on the substrate includes one or more halogens selected from chlorine, fluorine, nitrogen compounds, and carbon compounds, in the dielectric film activator, nitrogen compounds and carbon compounds are more preferable than chlorine and fluorine to react with iodine-based and bromine-based activators.

As a specific example, the dielectric film activator may be a mixed gas obtained by mixing hydrogen iodide (HI) and hydrogen bromide (HBr) in an inert gas in a mole fraction of 1 to 99.

In addition, the dielectric film activator may be an iodine doner; iodine ion; or iodine radical, and is preferably a substance represented by the structure in terms of smooth ligand exchange.

In this case, by suppressing side reactions, process by-products in the dielectric film may be reduced, corrosion or deterioration may be reduced, and the growth rate of a thin film may be controlled. In addition, a stoichiometric oxidation state may be reached when a metal oxide film is formed, and the thickness uniformity of the dielectric film may be greatly improved.

As a specific example, the dielectric film activator may be 3 N to 15 N hydrogen iodide, a gas mixture containing 1 to 99% by weight of 3 N to 15 N hydrogen iodide and an inert gas in an amount that allows a total weight to be 100% by weight, or an aqueous solution mixture containing 0.5 to 70% by weight of 3 N to 15 N hydrogen iodide and water in an amount that allows a total weight to be 100% by weight. Here, when the inert gas is nitrogen, helium, or argon with a purity of 4 N to 9 N, process by-products may be significantly reduced, step coverage may be excellent, thin film density may be improved, and the electrical properties of a thin film may be excellent.

Preferably, the dielectric film activator may be 5 N to 6 N hydrogen iodide, a gas mixture containing 1 to 99% by weight of 5 N to 6 N hydrogen iodide and an inert gas in an amount that allows a total weight to be 100% by weight, or an aqueous solution mixture containing 0.5 to 70% by weight of 5 N to 6 N hydrogen iodide and water in an amount that allows a total weight to be 100% by weight. Here, the inert gas may be nitrogen, helium, or argon with a purity of 4 N to 9 N. In this case, side reactions may suppressed, and the thin film growth rate may be controlled. Thus, process by-products in a thin film may be reduced, corrosion or deterioration may be prevented, and the crystallinity of a thin film may be improved. Thus, even when a thin film is formed on a substrate having a complex structure, thin film density (step coverage) and the thickness uniformity of a thin film may be greatly improved.

The dielectric film activator may be preferably a compound having a purity of 99.9% or more, 99.95% or more, or 99.99% or more. For reference, when using a compound having a purity of less than 99%, impurities may remain in the dielectric film or cause side reactions with the precursor or reactant, so it is desirable to use a substance having a purity of 99% or more.

The vapor pressure may be 1 atm at 180 to 240 K. Within this range, since materials are smoothly transferred into the chamber, the thickness uniformity and dielectric properties of the dielectric film may be excellent, and film quality may be excellent.

In the present invention, the dielectric film activator may be injected in a gaseous state, a precursor compound described below may be vaporized and injected, and then a plasma post-treatment step may be included. In this case, the growth rate of the dielectric film may be improved, and process by-products may be reduced.

The thin film (including a dielectric film) may be a deposition film.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

The reaction gas may include one or more selected from H₂O, H₂O₂, N₂O, NO₂, O₂, O₃, and O radical.

The dielectric film may be manufactured by various methods, for example, by the following methods.

As a first step, on a substrate loaded into a chamber, a precursor compound having a ligand including a transition metal and an alkyl, an alkylamine or a halogen, a halogen and oxygen or carbon and hydrogen simultaneously, or a precursor compound having a ligand including nitrogen and carbon simultaneously may be injected.

The ligand may include one or more selected from alkyl and alkylamine, chlorine, and fluorine, preferably alkylamine having excellent reactivity.

For example, the structure containing both carbon and hydrogen may be a cyclopentadienyl (Cp) group.

In the present disclosure, for example, the precursor compound may be delivered into the deposition chamber by vapor flow control (VFC) using a mass flow controller (MFC), mass flow control (MFC) using a liquid mass flow controller (LMFC), or a liquid delivery system (LDS).

At this time, a mixed gas of one or more selected from the group consisting of argon (Ar), nitrogen (N₂), and helium (He) may be used as a carrier gas or dilution gas to move the precursor compound onto the substrate, without being limited thereto.

In the present disclosure, for example, an inert gas, preferably the carrier gas or dilution gas may be used as the purge gas.

The chamber may be an atomic layer deposition (ALD) chamber, a plasma-enhanced atomic layer deposition (PEALD) chamber, a chemical vapor deposition (CVD) chamber, a plasma-enhanced chemical vapor deposition (PECVD) chamber, a metalorganic chemical vapor deposition (MOCVD) chamber, or a low pressure chemical vapor deposition (LPCVD) chamber.

The substrate loaded into the chamber may include a semiconductor substrate such as a silicon substrate or silicon oxide.

The substrate may further have a conductive layer or insulating layer formed thereon.

The substrate may be maintained at 50 to 500° C., or 80 to 500° C.

For example, the substrate may be heated to 50 to 500° C., as a specific example, 80 to 500° C., 100 to 800° C., or 200 to 500° C. The dielectric film activator or precursor compound may be injected onto the substrate in an unheated or heated state, and depending on the deposition efficiency, the dielectric film activator or precursor compound may be injected in an unheated state and then the heating conditions may be adjusted during the deposition process. For example, the dielectric film activator or precursor compound may be injected onto the substrate heated to 50 to 500° C. for 1 to 20 seconds.

Regarding the amount (mg/cycle) of the precursor compound injected into the chamber, the input amount (mg/cycle) ratio of the dielectric film activator used in the second step described below to the precursor compound injected into the chamber may be, for example, 1:1 to 1:100, preferably 1:1 to 1:50, more preferably 1:1 to 1:25. Within this range, thin film density may be greatly improved, and process by-products may be significantly reduced.

The first step may include one or more purging steps using an inert gas. The inert gas may be the carrier gas or dilution gas described above.

The amount of purge gas injected into the chamber in the step of purging the unabsorbed precursor compound is not particularly limited as long as the amount is sufficient to remove the unabsorbed precursor compound, and may be, for example, may be 10 to 100,000 times, preferably 50 to 50,000 times, more preferably 100 to 10,000 times the volume of the precursor compound injected into the chamber. Within this range, by sufficiently removing the unabsorbed precursor compound, a dielectric film may be formed evenly and deterioration of film quality may be prevented. Here, the input amounts of the purge gas and precursor compound are each based on one cycle, and the volume of the precursor compound refers to the volume of the vaporized precursor compound.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

As a second step, a dielectric film activator is injected into the substrate to replace the leaving group of the precursor adsorbed on the substrate with the halogen of the activator. In this case, the leaving group of the precursor adsorbed on the substrate is effectively changed to the halogen of the activator, and a thin film is formed without any gaps in the crystal lattice. Thus, thin film density may be improved, and the dielectric properties and thickness uniformity of a thin film may be greatly improved.

For example, the halogen may include one or more selected from iodine and bromine, preferably iodine.

The feeding time (sec) of the dielectric film activator on the surface of the substrate is preferably 0.01 to 10 seconds, more preferably 0.02 to 3 seconds, still more preferably 0.04 to 2 seconds, still more preferably 0.05 to 1 second per cycle. Within this range, the growth rate of a thin film may be reduced, the density of a thin film may be improved, and economic efficiency may be excellent.

In the present disclosure, the supply amount of the dielectric film activator is based on a flow rate of 1 to 300 sccm/cycle at a chamber volume of 15 to 20 L, and more specifically, based on a flow rate of 10 to 100 sccm/cycle at a chamber volume of 18 L.

In the present disclosure, a method of transporting gas using a mass flow controller (MFC) method may be used to deliver the dielectric film activator to the deposition chamber.

The second step may include one or more purging steps using an inert gas. In the present disclosure, as the purge gas, for example, a carrier gas or a dilution gas may be used.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

The amount of purge gas injected into the chamber in the step of purging the unabsorbed dielectric film activator is not particularly limited as long as the amount is an amount sufficient to remove the unabsorbed dielectric film activator, but may be, for example, 10 to 100,000 times, preferably 50 to 50,000 times, more preferably 100 to 10,000 times. Within this range, by sufficiently removing the unabsorbed dielectric film activator, a thin film may be evenly formed, and deterioration of film quality may be prevented. Here, the input amounts of the purge gas and dielectric film activator are each based on one cycle, and the volume of the dielectric film activator refers to the volume of the vaporized dielectric film activator.

As a specific example, the deposition filler is injected at a flow rate of 100 sccm and an injection time of 0.5 sec (per cycle). In the step of purging an unabsorbed deposition filler, when the purge gas is injected at a flow rate of 3000 sccm and an injection time of 5 seconds (per cycle), the amount of purge gas injected is 300 times the amount of deposition filler injected.

Next, as a third step, a thin film in which a heteroatom is bonded to a transition metal may be formed by injecting a reaction gas into the substrate.

For example, the reaction gas may include one or more selected from H₂O, H₂O₂, N₂O, NO₂, O₂, O₃, and O radical.

The thin film may include a structure in which a halogen is directly bonded to a group 4 metal.

For example, the method of forming a dielectric film may be performed at a deposition temperature of 50 to 800° C., preferably 100 to 700° C., more preferably 200 to 650° C., still more preferably 220 to 500° C. Within this range, process characteristics may be implemented, and a thin film having excellent film quality may be formed.

For example, the method of forming a dielectric film may be performed under a deposition pressure of 0.01 to 20 Torr, preferably 0.1 to 20 Torr, more preferably 0.1 to 10 Torr, most preferably 0.3 to 7 Torr. Within this range, a thin film of uniform thickness may be obtained.

In the present disclosure, the deposition temperature and the deposition pressure may be measured as temperature and pressure formed within the deposition chamber, or as temperature and pressure applied to the substrate within the deposition chamber.

The second step may preferably include a step of increasing the temperature inside the chamber to the deposition temperature before introducing the dielectric film activator into the chamber; and/or a step of purging by injecting an inert gas into the chamber before introducing the dielectric film activator into the chamber.

The third step may include a purging step using an inert gas.

In the purging step performed immediately after the reaction gas supply step, the amount of purge gas introduced into the chamber may be, for example, 10 to 10,000 times, preferably 50 to 50,000 times, more preferably 100 to 10,000 times the volume of reaction gas introduced into the chamber. Within this range, the desired effects may be sufficiently achieved. Here, the input amounts of purge gas and reaction gas are based on one cycle.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

In the method of forming a dielectric film, when necessary, the unit cycle may be repeated 1 to 99, 999 times, preferably 10 to 10,000 times, more preferably 50 to 5,000 times, still more preferably 100 to 2,000 times. Within this range, the desired thickness of a thin film may be obtained, the content of by-product carbon compounds may be reduced, and thin film density may be improved.

As a specific example, in the method of manufacturing a dielectric film, to deposit a dielectric film on a substrate positioned in the chamber, the above-described dielectric film activator and a precursor compound or a mixture of the precursor compound and a non-polar solvent are prepared, respectively.

Then, the prepared precursor compound or a mixture of the precursor compound and a non-polar solvent is injected into a vaporizer, changes into a vapor phase, is transferred to a deposition chamber, and is adsorbed on the substrate. Then, the ligand of the precursor compound is replaced by the dielectric film activator, and the unabsorbed precursor compound is purged.

Next, the prepared dielectric film activator is injected into the vaporizer, changed into a vapor phase, transferred to the deposition chamber, and adsorbed onto the substrate. Then, purging is performed to remove the unabsorbed dielectric film activator.

In the present disclosure, for example, the dielectric film activator and precursor compound may be transferred to the deposition chamber using a mass flow controller (MFC).

At this time, a mixed gas of one or more selected from the group consisting of argon (Ar), nitrogen (N₂), and helium (He) may be used as a carrier gas or dilution gas to move the dielectric film activator and the precursor compound onto the substrate, without being limited thereto.

In the present disclosure, for example, an inert gas, preferably the carrier gas or dilution gas may be used as the purge gas.

Next, a heteroatom-containing gas is supplied. As the heteroatom-containing gas, a reaction gas commonly used in the technical field to which the present invention pertains may be used in the present invention without particular limitation. Preferably, the heteroatom-containing gas may include an oxidizing agent. The oxidizing agent and the precursor compound adsorbed on the substrate react to form an oxide film.

Preferably, the oxidizer may be oxygen gas (O₂), ozone gas (O₃), or a mixture of nitrogen gas and oxygen gas.

Next, unreacted residual reaction gas is purged using an inert gas. Accordingly, in addition to excess reaction gas, generated byproducts may also be removed.

As described above, in the method of forming a dielectric film, for example, a step of adsorbing a precursor compound onto a substrate, a step of purging an unabsorbed precursor compound, a step of supplying a dielectric film activator onto a substrate, a step of purging an unabsorbed dielectric film activator, a step of supplying a reaction gas, and a step of purging a residual reaction gas may be set as a unit cycle. To form a dielectric film of desired thickness, the unit cycle may be repeated.

For example, the unit cycle may be repeated 1 to 99,999 times, preferably 10 to 1,000 times, more preferably 50 to 5,000 times, still more preferably 100 to 2,000 times. Within this range, the desired dielectric film properties may be well expressed.

When the injection time of the precursor compound and the purge time in the first step are a and b, respectively, the injection time of the alkyl-free halogenide and the purge time in the second step are c and d, respectively, and the injection time of the heteroatom-containing gas and the purge time in the third step are e and f, respectively, 0.1≤a≤10, 2a≤b≤4a, 0.1<c≤10, 2c≤d≤8c, 2<e≤10, and 2e≤b≤8e may be satisfied at the same time.

When the injection and purge of the precursor compound and dielectric film activator and the injection and purge of the heteroatom-containing gas are considered as one cycle, all of the following two conditions may be satisfied: 1) The deposition rate of the dielectric film on SiO₂ is 1 Å/cycle or more. 2) The density of the dielectric film is 9.8 g/cm³ or more.

When the injection and purge of the precursor compound and dielectric film activator and the injection and purge of the heteroatom-containing gas are considered as one cycle, all of the following two conditions may be satisfied: 1) The deposition rate of the dielectric film on SiO₂ is 1 to 2 Å/cycle. 2) The density of the dielectric film is 9.8 to 10.5 g/cm³.

For example, the method of manufacturing a dielectric film may be performed using a dielectric film manufacturing apparatus including an ALD chamber, a corrosion-resistant MFC including gold seal for quantitative injection of the dielectric film activator, a first transport means for transferring the quantitatively injected dielectric film activator into the ALD chamber, a second vaporizer that vaporizes the precursor adsorbed on the substrate, and a second transport means for transporting the vaporized precursors adsorbed on the substrate into the ALD chamber. Here, the vaporizer and transport means are not particularly limited as long as the vaporizer and transport means are a vaporizer and transport means commonly used in the technical field to which the present invention belongs.

A thin film deposited using the dielectric film activator described above is included.

The thin film may be a dielectric film.

The thin film may have a multi-layer structure with two or more layers.

For example, the thin film may be obtained by the reaction between the activated substrate-adsorbed precursor represented by the structure of Chemical Formula 1 described above and a reaction gas. In this case, by using the activated substrate-adsorbed precursor, the content of by-product carbon compounds may be reduced, so that a high-quality thin film may be manufactured.

For example, the decrease in the content of by-product carbon compounds between the precursor adsorbed on the activated substrate and the reaction gas may be due to a decrease in the activation energy of the precursor adsorbed on the activated substrate compared to the activation energy of the precursor adsorbed on the substrate.

The dielectric film may have a deposition rate of 1.0 Å/cycle or more, or 1.0 to 2.0 Å/cycle as measured using an ellipsometer (based on a thin film deposited at 300° C.) on SiO₂ or Si. Within this range, thin film uniformity and deposition productivity may be improved.

The dielectric film may have a thin film density of 9.5 g/cm³ or more, 9.8 g/cm³ or more, or 9.8 to 10.3 g/cm³ as measured on SiO₂ or Si. Within this range, dielectric properties may be improved.

The dielectric film may have a carbon impurity content of 1000 counts/s or less, 715 counts/s or less, or 700 counts/s or less as measured by SIMS (based on a thin film deposited at 300° C.) on SiO₂ or Si. Within this range, the leakage of electrons may be significantly reduced, and thus dielectric properties may be improved.

The dielectric film may contain an iodine atom in an amount of 50 counts/s or more, or 65 counts/s as measured by SIMS. Within this range, the effect of increasing the dielectric constant may be obtained by increasing the thin film density.

The dielectric film may have a deposition thickness of 410 counts/s or less, or 300 counts/s or less as measured SIMS on SiO₂ or Si (based on a thin film deposited at 400° C.). Within this range, the leakage of electrons may be significantly reduced, and thus dielectric properties may be improved.

The dielectric film may include the aforementioned film composition alone or as a selective area, but is not limited thereto, and also includes Si, SiH, SiOH, and SiO₂.

In addition to commonly used DRAM, the dielectric film may be applied to semiconductor devices as a dielectric film or insulating film for NAND or Logic elements.

For example, the dielectric film may contain a halogen compound in an amount of 30,000 counts/s or less as measured by SIMS.

In addition, the present invention provides a semiconductor substrate. The semiconductor substrate is fabricated using the method of forming a dielectric film of the present invention or includes the dielectric film. In this case, the thin film density (step coverage) and thickness uniformity of the dielectric film may be greatly improved, and the density and dielectric properties of the dielectric film may be excellent.

The manufactured dielectric film preferably has a deposition rate of 1 Å/cycle or more and a density of 9.8 g/cm³ or more on SiO₂. Within this range, the dielectric film has excellent performance as a diffusion barrier, and the dielectric properties thereof may be improved, without being limited thereto.

Here, for example, impurities halogens remaining on the dielectric film may include Cl₂, Cl, or Cl⁻. As the amount of halogen residues within the dielectric film decreases, the film quality increases.

In addition, as the amount of carbon residues within the dielectric film decreases, the dielectric properties increase.

For example, when necessary, the dielectric film may have a multilayer structure of two or more layers, a multilayer structure of three or more layers, or a multilayer structure of two or three layers. As a specific example, the multilayer film with a two-layer structure may have a lower layer-middle layer structure, and the multilayer film with a three-layer structure may have a lower layer-middle layer-upper layer structure.

For example, the lower layer may be formed of one or more selected from the group consisting of Si, SiO₂, MgO, Al₂O₃, Cao, ZrSiO₄, ZrO₂, HfSiO₄, Y₂O₃, HfO₂, LaLuO₂, Si₃N₄, Sro, La₂O₃, Ta₂O₅, Bao, and TiO₂.

For example, the middle layer may be formed of TiₓN_{y}, preferably TN.

For example, the upper layer may be formed of one or more selected from the group consisting of W and Mo.

According to the present invention, a semiconductor device including the semiconductor substrate described above may be provided.

For example, the semiconductor device may be low-resistive metal gate interconnects, a high-aspect-ratio 3D metal-insulator-metal (MIM) capacitor, a DRAM trench capacitor, 3D Gate-All-Around (GAA), or 3D NAND flash memory.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

As precursor compounds, a compound having a structure represented by Chemical Formula 1-1 below and a compound having a structure represented by Chemical Formula 4 below were prepared, respectively.

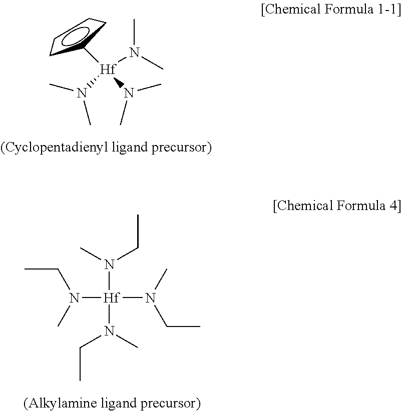

5 N HI as a dielectric film activator was prepared.

An ALD deposition process was performed using the precursor compound and dielectric film activator with the deposition process sequence according to the present invention as one cycle.

The specific experimental methods for Examples 1 and 2 and Comparative Examples 1 and 2 are as follows.

### Example 1

The precursor compound having the structure represented by Chemical Formula 1-1 was placed in a canister maintained at 25° C. and supplied to a separate vaporizer heated to 150° C. at a flow rate of 0.05 g/min using a liquid mass flow controller (LMFC) at room temperature. The precursor compound vaporized in the vaporizer was injected into the deposition chamber using a vapor flow controller (VFC) for 1 second, and then argon gas was supplied at 3000 sccm for 5 seconds to perform argon purging. At this time, the pressure inside the reaction chamber was controlled to 2.5 Torr.

Next, 5 N HI as a dielectric film activator was placed in a canister and supplied to the chamber at 100 sccm/cycle using a mass flow controller (MFC) at room temperature. After the dielectric film activator was introduced into the deposition chamber loaded with a substrate for 2 seconds, argon gas was supplied at 3000 sccm for 8 seconds to perform argon purging. At this time, the pressure inside the reaction chamber was controlled to 2.5 Torr.

Next, 1000 sccm of ozone as a reactive gas was injected into the reaction chamber for 3 seconds, followed by argon purging for 9 seconds. At this time, a substrate on which a dielectric film is to be formed was heated to 300° C., and SiO₂ was formed on top of the Si substrate.

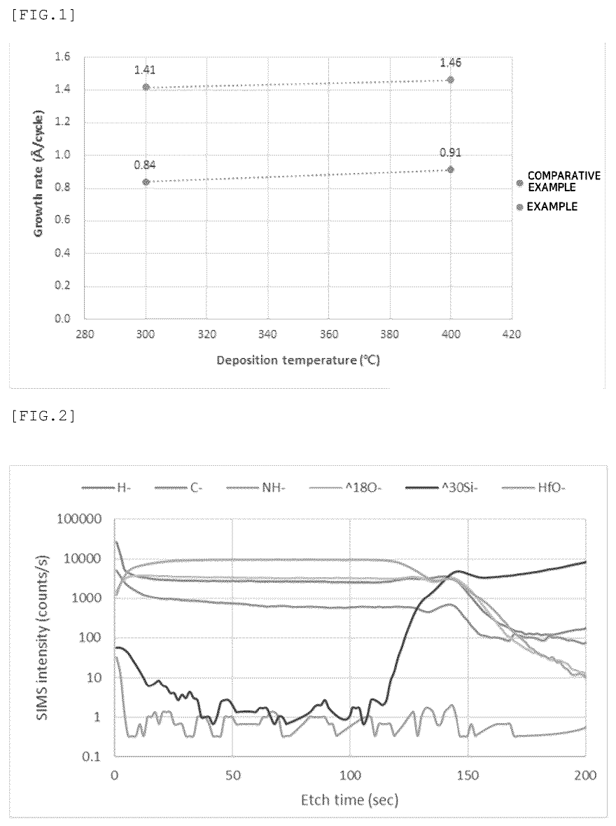

By repeating this process 200 to 400 times, dielectric films were manufactured at deposition rates according to deposition temperatures shown in FIG. 1 below.

As shown in FIG. 1 below, each dielectric film has a deposition rate of 1.41 Å/cycle.

In addition, the density of the dielectric film was measured using X-ray reflectometry (XRR) equipment. The measured density was 9.83 g/cm³.

In addition, the impurity content of the dielectric film was measured.

Here, impurities such as H—, C—, NH—, ¹⁸O—, and ³⁰Si— were measured using secondary-ion mass spectrometry (SIMS) equipment.

Specifically, the impurity value was verified in the SIMS graph by considering the impurity content (counts) when an ion sputter was used to axially dig into the deposition film and the sputter time was 50 seconds with little contamination on the surface of a substrate.

From the confirmed SIMS results, the average impurity content of carbon (C) in the dielectric film was 694 counts/s. In addition to carbon, the content of H impurities remaining as process by-products was reduced from 3340 counts/s to 2600 counts/s.

### Example 2

The precursor compound having the structure represented by Chemical Formula 4 was placed in a canister maintained at 25° C. and supplied to a separate vaporizer heated to 150° C. at a flow rate of 0.05 g/min using a liquid mass flow controller (LMFC) at room temperature. The precursor compound vaporized in the vaporizer was injected into the deposition chamber using a vapor flow controller (VFC) for 1 second, and then argon gas was supplied at 3000 sccm for 5 seconds to perform argon purging. At this time, the pressure inside the reaction chamber was controlled to 2.5 Torr.

Next, 5 N HI as a dielectric film activator was placed in a canister and supplied to the chamber at 100 sccm/cycle using a mass flow controller (MFC) at room temperature. After the dielectric film activator was introduced into the deposition chamber loaded with a substrate for 2 seconds, argon gas was supplied at 3000 sccm for 8 seconds to perform argon purging. At this time, the pressure inside the reaction chamber was controlled to 2.5 Torr.

Next, 1000 sccm of ozone as a reactive gas was injected into the reaction chamber for 3 seconds, followed by argon purging for 9 seconds. At this time, a substrate on which a dielectric film is to be formed was heated to 300° C., and SiO₂ was formed on top of the Si substrate.

By repeating this process 200 to 400 times, dielectric films were manufactured at deposition rates according to deposition temperatures. The deposition rate of the dielectric film was 1.46 Å/cycle.

In addition, the density of the dielectric film was measured using X-ray reflectometry (XRR) equipment. The measured density was 10.08 g/cm³.

In addition, for the dielectric film, the average impurity content of carbon (C) in the dielectric film measured using secondary-ion mass spectrometry (SIMS) equipment was 243 counts/s. In addition to carbon, the content of H impurities remaining as process by-products was reduced.

### Comparative Example 1

The same process as in Example 1 was performed, except that a dielectric film was manufactured without using 5 N HI as the dielectric film activator, and the measurement results are shown in FIG. 1 below.

As shown in FIG. 1 below, the deposition rate increase rate (D/R (dep.rate) increase rate) of the dielectric film is 0.84 Å/cycle.

As a result, Comparative Example 1 was confirmed to be approximately 33% defective compared to Example 1.

In addition, the density of the dielectric film was measured using X-ray reflectometry (XRR) equipment. The measured average density was 9.71 g/cm³, showing that Comparative Example 1 is defective compared to Example 1.

In addition, for the dielectric film, the impurity content of carbon (C) in the dielectric film measured using SIMS was 927 counts/s, showing that Comparative Example 1 is approximately 33% defective compared to Example 1.

### Comparative Example 2

The same process as in Example 2 was performed, except that a dielectric film was manufactured without using 5 N HI as the dielectric film activator, and the measurement results are shown in FIG. 1 below.

The deposition rate increase rate (D/R (dep.rate) increase rate) of the dielectric film was 0.91 Å/cycle, showing that Comparative Example 2 is approximately 60% defective compared to Example 1.

In addition, the density of the dielectric film was measured using X-ray reflectometry (XRR) equipment. The measured average density was 10.08 g/cm³, showing that Comparative Example 2 is defective compared to Example 1.

In addition, the impurity content of the dielectric film was measured, and the impurity content of carbon (C) in the dielectric film measured by SIMS was 243 counts/s, showing that Comparative Example 2 is approximately 42% defective compared to Example 1.

Based on these results, in the case of using the dielectric film activator having a predetermined structure according to the present invention, compared to Comparative Examples without using the dielectric film activator of the present invention, deposition thickness, deposition rate, and thin film density were greatly improved. In addition, due to excellent impurity reduction characteristics, dielectric properties were improved.

In particular, compared to Comparative Example 1 without using the dielectric film activator of the present invention, in the case of Example 1 using the dielectric film activator of the present invention, even though the dielectric film was manufactured at a low temperature of 300° C., the deposition rate increase rate per cycle of the dielectric film was 10% or more, the density of the dielectric film was 10% or more, and the impurity reduction rate was 60% or more, showing excellent properties.

### Additional Example 1

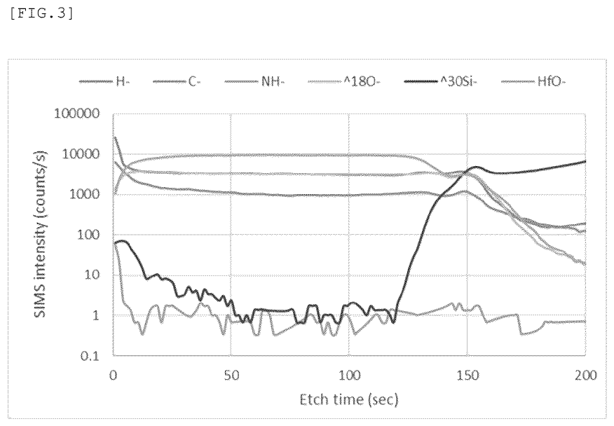

The process of injecting a precursor (CpHf) and injecting an activator (HI) into an Si substrate at 300° C. and reacting with reactant (O₃) was repeated to obtain a thin film having a thickness of about 13 nm. According to the secondary-ion mass spectrometry (SIMS) analysis, the C impurity value was verified by considering the C impurity content (counts) when an ion sputter was used to axially dig into the thin film and the sputter time was 50 seconds with little contamination on the surface of a substrate. As shown in FIG. 2, the C impurity value is about 700 counts/s.

### Additional Comparative Example 1

The process of injecting a precursor (CpHf) into an Si substrate at 300° C. and reacting with reactant (O₃) was repeated to obtain a thin film having a thickness of about 13 nm.

According to the secondary-ion mass spectrometry (SIMS) analysis, the C impurity value was verified by considering the C impurity content (counts) when an ion sputter was used to axially dig into the thin film and the sputter time was 50 seconds with little contamination on the surface of a substrate. As shown in FIG. 3, the C impurity value is about 1100 counts/s.

Therefore, when the predetermined compound was used as the dielectric film activator of the present invention, the thickness, deposition rate increase rate, density, and dielectric properties of a dielectric film were improved, and impurity reduction characteristics was excellent. Thus, even when a substrate having a complex pattern was used, the dielectric film was effectively formed.

1. A dielectric film activator providing an activated substrate-adsorbed precursor by exchanging a first ligand directly connected to a central metal of a precursor adsorbed on a substrate with a second ligand comprised in the dielectric film activator.

2. The dielectric film activator according to claim 1, wherein the central metal of the precursor adsorbed on the substrate is a group 4 atom.

3. The dielectric film activator according to claim 1, wherein the precursor molecule adsorbed on the substrate is selected from a structure represented by Chemical Formula 1 below and a structure represented by Chemical Formula 2 below: 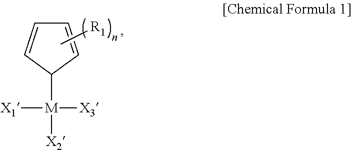
wherein M is Zr or Hf; R₁ is independently hydrogen or an alkyl group having 1 to 4 carbon atoms; n is an integer from 0 to 5; X′₁, X′₂, and X′₃ are independently selected from —NR′₁R′₂ or —OR′₃, Cl, or F; and R′₁ to R′₃ are independently hydrogen or an alkyl group having 1 to 6 carbon atoms. 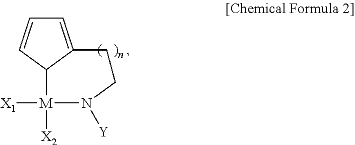
wherein M is Zr or Hf; X₁ and X₂ are independently —NR₁R₂ or —OR₃, Cl, or F; R₁ to R₃ are independently hydrogen or an alkyl group having 1 to 6 carbon atoms; Y is an alkyl having 1 to 6 carbon atoms; and n is 1 or 2.

4. The dielectric film activator according to claim 1, wherein the first and second ligands independently comprise a halogen, a halogen and oxygen or carbon and hydrogen, or nitrogen and carbon simultaneously.

5. The dielectric film activator according to claim 1, wherein the first ligand is the ligand of Chemical Formula 1 or 2, the ligand of the precursor adsorbed on the substrate comprises one or more selected from chlorine, fluorine, and bromine in addition to the first ligand, and the dielectric film activator comprises one or more halogens selected from iodine and bromine.

6. The dielectric film activator according to claim 1, wherein the dielectric film activator is hydrogen iodide (HI), hydrogen bromide (HBr), or a mixed gas obtained by mixing hydrogen iodide (HI) or hydrogen bromide (HBr) and an inert gas in a molar fraction of 1 to 99.

7. The dielectric film activator according to claim 1, wherein reaction with a reaction gas injected before or after injection of the precursor is promoted by the activated substrate-adsorbed precursor, and at the same time, a content of residual carbon compound impurities is reduced.

8. The dielectric film activator according to claim 7, wherein reduction in the content of residual carbon compound impurities comprises reduction in a content of by-product carbon-oxygen impurities generated by bonding between a precursor desorption ligand and a reactant and reduction in a content of carbon compound impurities not desorbed the precursor.

9. The dielectric film activator according to claim 8, wherein reduction in the content of non-desorbed carbon compound impurities is due to exchange of the ligand of the precursor adsorbed on the substrate with a dielectric film activator comprised in the dielectric film activator.

10. The dielectric film activator according to claim 1, wherein a precursor adsorption state before the ligand exchange is represented by Chemical Formula 3-1 below, and a precursor adsorption state after the ligand exchange is represented by Chemical Formula 3-2 below. 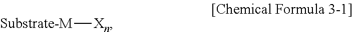
wherein M is Hf or Zr; n is an integer from 1 to 4; and X is ligand species of Chemical Formulas 1 and 2, F, or Cl and is the same or different. 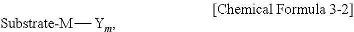
wherein M is Hf or Zr; m is an integer from 1 to 4; and Y is Br or I.

11. The dielectric film activator according to claim 1, wherein the substrate is a silicon wafer, insulating film, or dielectric film having an —H or —OH terminal group.

12. The dielectric film activator according to claim 1, wherein the dielectric film is a deposition film, wherein the deposition comprises atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

13. A semiconductor substrate comprising a substrate; and a dielectric film,
wherein the dielectric film is a film deposited using the dielectric film activator according to claim 1.

14. The semiconductor substrate according to claim 13, wherein the dielectric film has a multi-layer structure with two or more layers.

15. The semiconductor substrate according to claim 13, wherein the dielectric film has a thin film density of 9.5 g/cm³ or more, contains carbon impurities in an amount of 1000 counts/s or less as measured by SIMS, and contains an iodine atom in an amount of 50 counts/s or more as measured by SIMS.

16. A semiconductor device comprising the semiconductor substrate according to claim 13.
